(19) United States
(12) Patent Application Publication
(10) Pub. No.: US 2026/0047358 A1
(43) Pub. Date: Feb. 12, 2026

(54) HIGH GROWTH RATE SELECTIVE SI:P PROCESS

(71) Applicant: Applied Materials, Inc., Santa Clara, CA (US)

(72) Inventors: Chen-Ying WU, Santa Clara, CA (US); Abhishek DUBE, Fremont, CA (US); Tahereh TAGHVAEE, Mountain View, CA (US); Manoj VELLAIKAL, Sunnyvale, CA (US); Nicolas Louis BREIL, San Jose, CA (US)

(21) Appl. No.: 19/291,441

(22) Filed: Aug. 5, 2025

Related U.S. Application Data
(60) Provisional application No. 63/679,889, filed on Aug. 6, 2024.

(51) Int. Cl. H01L 21/02; C30B 25/16; C30B 29/06; C30B 33/12; H01L 21/3065

(52) U.S. Cl. CPC H01L 21/02576; C30B 25/165; C30B 29/06; C30B 33/12; H01L 21/02532; H01L 21/3065

(57) ABSTRACT

Embodiments of the present disclosure generally relate to methods and processes to selectively deposit Si:P layers onto a semiconductor structure. More specifically, embodiments described herein provide for methods for enhancing epitaxial deposition of Si:P layers onto semiconductor structures at lower temperatures. In some embodiments, a method includes positioning a substrate within a processing volume of a processing chamber, introducing a process gas such as a silicon source and a dopant gas to the processing chamber, and forming an epitaxial layer on a surface of the substrate at a processing temperature of about 450° C. or less. The partial pressure of the silicon source is preferably about 10 Torr to about 300 Torr.

### CROSS-REFERENCE TO RELATED APPLICATION

This application claims the benefit of U.S. Provisional Patent Application Ser. No. 63/679,889, filed Aug. 6, 2024, which is incorporated by reference in its entirety.

### BACKGROUND

### Field

Embodiments of the present disclosure generally relate to methods and processes to selectively deposit Si:P layers onto a semiconductor structure. More specifically, embodiments described herein provide for methods for enhancing epitaxial deposition of Si:P layers onto semiconductor structures at lower temperatures.

### Description of the Related Art

The integration density of semiconductor devices has continuously improved through design-rule shrinkage. As feature size decreases, new methods and/or materials are needed to meet fabrication constraints. One such technique is selective deposition/etch processes for epitaxially depositing a crystalline Si:P layer onto a semiconductor substrate at temperatures lower than conventional processes.

Current selective deposition/etch techniques for epitaxially depositing a crystalline Si:P layer onto a semiconductor substrate cannot be performed at low temperatures (e.g., 400° C. or less) at satisfactory crystalline growth rates. Thus, there is a need to develop new Si:P selective deposition processes capable of high crystalline growth rates at low processing temperature regimes.

### SUMMARY

Embodiments of the present disclosure generally relate to methods and processes to selectively deposit Si:P layers onto a semiconductor structure. More specifically, embodiments described herein provide for methods for enhancing epitaxial deposition of Si:P layers onto semiconductor structures at lower temperatures.

In some embodiments, a method includes positioning a substrate within a processing volume of a processing chamber, introducing a process gas such as a silicon source and a dopant gas to the processing chamber, and forming an epitaxial layer on a surface of the substrate at a processing temperature of about 450° C. or less. The partial pressure of the silicon source is preferably about 10 Torr to about 300 Torr.

In some embodiments, a method includes positioning a substrate within a processing volume of a processing chamber, introducing a process gas including a silicon source and a dopant source to the processing chamber, and forming an epitaxial layer on a surface of the substrate. The epitaxial layer includes an amorphous portion and a crystalline portion. The method includes maintaining the processing chamber at a processing temperature of about 450° C. or less during the formation of the epitaxial layer. The method further includes performing an etch operation to remove the amorphous portion from the epitaxial layer.

In some embodiments, a method includes positioning a substrate within a processing volume of a processing chamber, introducing a process gas including a silicon source and a dopant gas to the processing chamber, and forming an epitaxial layer on a surface of the substrate. The epitaxial layer includes an amorphous portion, a crystalline portion, and a phosphosilicate portion. The amorphous portion is disposed on a surface of the phosphosilicate portion. The method further includes performing an etch operation on the epitaxial layer to form a processed substrate. The etch operation includes at least one of a chemical etch operation or a plasma etch operation.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top plan view of a multi-chamber processing system, according to embodiments described herein.

FIG. 2 is a schematic cross sectional view of a processing chamber, according to an embodiment described herein.

FIG. 3 is a flow diagram depicting a method of processing a substrate, according to an embodiment described herein.

FIG. 4A is a cross-sectional illustration of a portion of a substrate, according to an embodiment described herein.

FIG. 4B is a cross-sectional illustration of a portion of a substrate, according to an embodiment described herein.

FIG. 5 is a flow diagram depicting a method of processing a substrate, according to an embodiment described herein.

FIG. 6A is a cross-sectional illustration of a portion of a substrate, according to an embodiment described herein.

FIG. 6B is a cross-sectional illustration of a portion of a substrate, according to an embodiment described herein.

FIG. 6C is a cross-sectional illustration of a portion of a substrate, according to an embodiment described herein.

FIG. 7 is a flow diagram depicting a method of processing a substrate, according to an embodiment described herein.

FIG. 8A is a cross-sectional illustration of a portion of a substrate, according to an embodiment described herein.

FIG. 8B is a cross-sectional illustration of a portion of a substrate, according to an embodiment described herein.

FIG. 9 is a flow diagram depicting a method of processing a substrate, according to an embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to methods and processes to selectively deposit Si:P layers onto a semiconductor structure. More specifically, embodiments described herein provide for methods for enhancing epitaxial deposition of Si:P layers onto semiconductor structures at lower temperatures, such as about 400° C. or lower.

Selective epitaxial deposition of Si:P layers onto semiconductor substrates at lower than conventional processing temperature has been achieved by utilizing processes disclosed herein. Generally, conventional processes for epitaxially depositing Si:P layers onto a substrate at temperatures below 450° C. have insufficient growth rates, if any formation occurs at all, due to the inactivity of the process gases at such temperatures. Furthermore, conventional processes for epitaxially depositing Si:P layers onto a substrate at temperatures greater than 550° C. may affect the thermal budget of other materials formed on the substrate. The epitaxial deposition processes disclosed herein utilize elevated gas pressures to enable epitaxial deposition of Si:P layers to be performed at processing temperatures of about 450° C. or less, such as about 400° C. or less, such as about 375° C. or less. To enable the selectivity of the epitaxial deposition processes disclosed herein, a selective etch gas and/or selective etch process may be integrated to effectively remove the amorphous portion of the Si:P epitaxial layer. The deposition and etch processes of the methods disclosed herein may be cyclically repeated and/or concurrently performed to form a crystalline Si:P epitaxial layer of suitable thickness on a semiconductor structure.

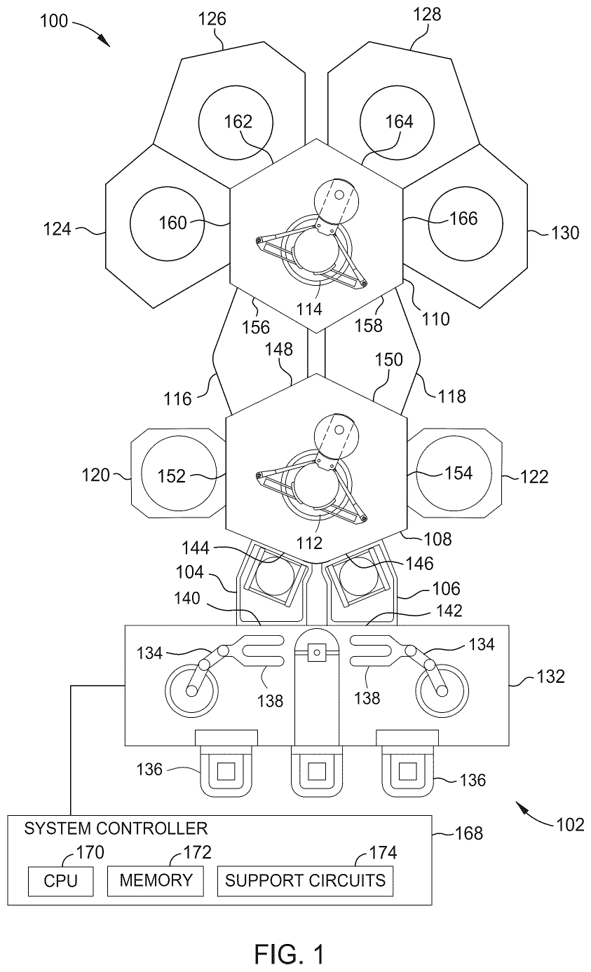

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

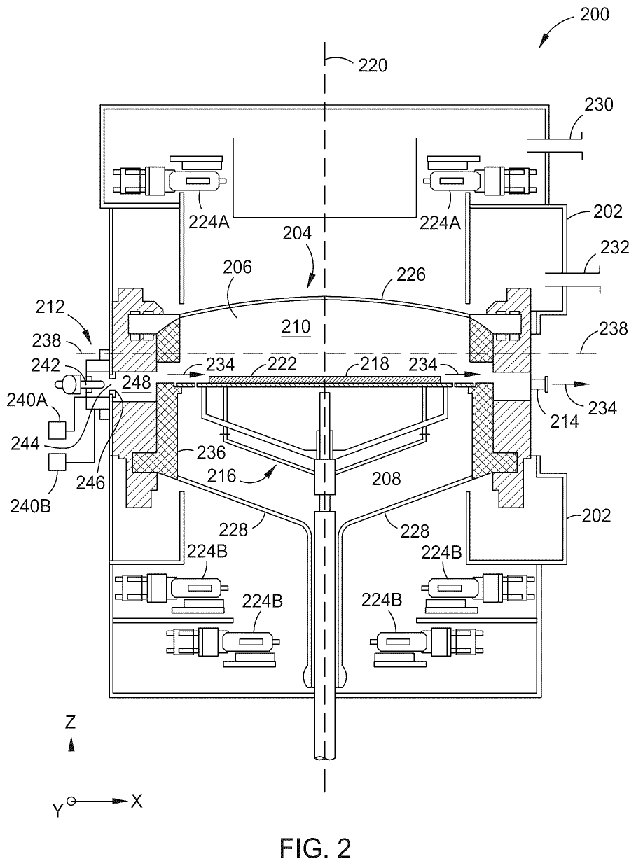

FIG. 2 is a cross sectional view of a processing chamber 200, according to one or more embodiments, that is adapted to perform an epitaxial (Epi) deposition process as detailed below. The processing chamber 200 may be the processing chamber 126, 128, or 130 shown in FIG. 1.

The processing chamber 200 includes a housing structure 202 made of a process resistant material, such as aluminum or stainless steel, for example 216L stainless steel. The housing structure 202 encloses various functioning elements of the processing chamber 200, such as a quartz chamber 204, which includes an upper quartz chamber 206, and a lower quartz chamber 208, in which a processing volume 210 is contained. Reactive species are provided to the quartz chamber 204 by a gas distribution assembly 212, and processing byproducts are removed from the processing volume 210 by an outlet port 214, which is typically in communication with a vacuum source (not shown).

A substrate support 216 is adapted to receive a substrate 218 that is transferred to the processing volume 210. The substrate support 216 is disposed along a longitudinal axis 220 of the processing chamber 200. The substrate support 216 may be made of a ceramic material or a graphite material coated with a silicon material, such as silicon carbide, or other process resistant material. Reactive species from precursor reactant materials are applied to a surface 222 of the substrate 218, and byproducts may be subsequently removed from the surface 222 of the substrate 218. Heating of the substrate 218 and/or the processing volume 210 may be provided by radiation sources, such as upper lamp modules 224A and lower lamp modules 224B.

In one embodiment, the upper lamp modules 224A and the lower lamp modules 224B are infrared (IR) lamps. Non-thermal energy or radiation from the lamp modules 224A and 224B travels through an upper quartz window 226 of the upper quartz chamber 206, and through a lower quartz window 228 of the lower quartz chamber 208. Cooling gases for the upper quartz chamber 206, if needed, enter through an inlet 230 and exit through an outlet 232. Precursor reactant materials, as well as diluent, purge and vent gases for the processing chamber 200, enter through the gas distribution assembly 212 and exit through the outlet port 214. While the upper quartz window 226 is shown as being curved or convex, the upper quartz window 226 may be planar or concave as the pressure on both sides of the upper quartz window 226 is substantially the same (i.e., atmospheric pressure).

The low wavelength radiation in the processing volume 210, which is used to energize reactive species and assist in adsorption of reactants and desorption of process byproducts from the surface 222 of the substrate 218, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 210 via the gas distribution assembly 212. Gas flows from the gas distribution assembly 212 and exits through the outlet port 214 as shown generally by a flow path 234. Combinations of component gases, which are used to clean/passivate a substrate surface, or to form the silicon and/or germanium-containing film that is being epitaxially grown, are typically mixed prior to entry into the processing volume 210. The overall pressure in the processing volume 210 may be adjusted by a valve (not shown) on the outlet port 214. At least a portion of the interior surface of the processing volume 210 is covered by a liner 236. In one embodiment, the liner 236 comprises a quartz material that is opaque. In this manner, the chamber wall is insulated from the heat in the processing volume 210.

The temperature of surfaces in the processing volume 210 may be controlled within a temperature range of about 200° C. to about 600° C., or greater, by the flow of a cooling gas, which enters through the inlet 230 and exits through the outlet 232, in combination with radiation from the upper lamp modules 224A positioned above the upper quartz window 226. The temperature in the lower quartz chamber 208 may be controlled within a temperature range of about 200° C. to about 600° C. or greater, by adjusting the speed of a blower unit which is not shown, and by radiation from the lower lamp modules 224B disposed below the lower quartz chamber 208. The pressure in the processing volume 210 may be between about 0.1 Torr to about 600 Torr, such as between about 5 Torr to about 30 Torr.

The temperature on the surface 222 of the substrate 218 may be controlled by power adjustment to the lower lamp modules 224B in the lower quartz chamber 208, or by power adjustment to both the upper lamp modules 224A overlying the upper quartz window 226, and the lower lamp modules 224B in the lower quartz chamber 208. The power density in the processing volume 210 may be between about 40 W/cm2 to about 400 W/cm2, such as about 80 W/cm2 to about 120 W/cm2.

In one aspect, the gas distribution assembly 212 is disposed normal to, or in a radial direction 238 relative to, the longitudinal axis 220 of the processing chamber 200 or the substrate 218. In this orientation, the gas distribution assembly 212 is adapted to flow process gases in the radial direction 238 across, or parallel to, the surface 222 of the substrate 218. In one processing application, the process gases are preheated at the point of introduction to the processing chamber 200 to initiate preheating of the gases prior to introduction to the processing volume 210, and/or to break specific bonds in the gases. In this manner, surface reaction kinetics may be modified independently from the thermal temperature of the substrate 218.

In operation, precursors used to form silicon (Si) and silicon phosphorus (Si:P) blanket or selective epitaxial films are provided to the gas distribution assembly 212 from one or more gas sources 240A and 240B. IR lamps 242 (only one is shown in FIG. 2) may be utilized to heat the precursors within the gas distribution assembly 212 as well as along the flow path 234. The gas sources 240A, 240B may be coupled the gas distribution assembly 212 in a manner adapted to facilitate introduction zones within the gas distribution assembly 212, such as a radial outer zone and a radial inner zone between the outer zones when viewed in from a top plan view. The gas sources 240A, 240B may include valves (not shown) to control the rate of introduction into the zones.

The gas sources 240A, 240B may include silicon precursors such as silanes, including silane (SiH₄), disilane (Si₂H₆), dichlorosilane (SiH₂Cl₂), hexachlorodisilane (Si₂Cl₆), dibromosilane (SiH₂Br₂), higher order silanes, derivatives thereof, and combinations thereof. In at least one embodiment, at least one of the gas sources 240A, 240B includes phosphine (PH₃), phosphorus trichloride (PCl₃), phosphorous tribromide (PBr₃), and phosphates such as tributyl phosphate (TBP)

The precursor materials enter the processing volume 210 through openings or holes 244 (only one is shown in FIG. 2) in the perforated plate 246 in this excited state, which in one embodiment is a quartz material, having the holes 244 formed therethrough. The perforated plate 246 is transparent to IR energy, and may be made of a clear quartz material. In other embodiments, the perforated plate 246 may be any material that is transparent to IR energy and is resistant to process chemistry and other processing chemistries. The energized precursor materials flow toward the processing volume 210 through the holes 244 in the perforated plate 246, and through channels 248 (only one is shown in FIG. 2). A portion of the photons and non-thermal energy from the IR lamps 242 also passes through the holes 244, the perforated plate 246, and channels 248 facilitated by a reflective material and/or surface disposed on the interior surfaces of the gas distribution assembly 212, thereby illuminating the flow path 234 of the precursor materials. In this manner, the vibrational energy of the precursor materials may be maintained from the point of introduction to the processing volume 210 along the flow path.

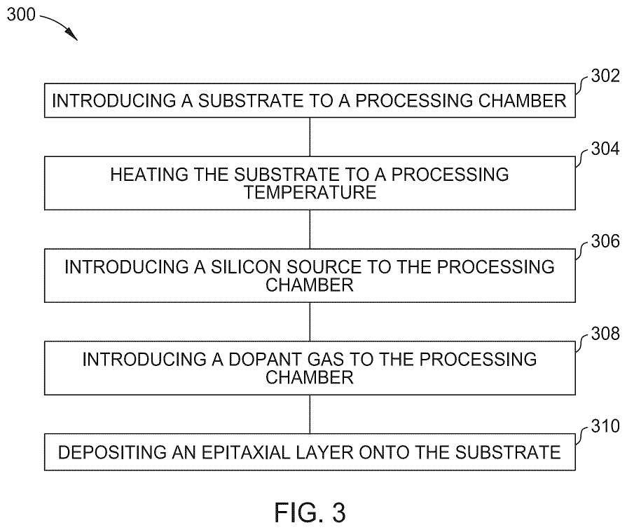

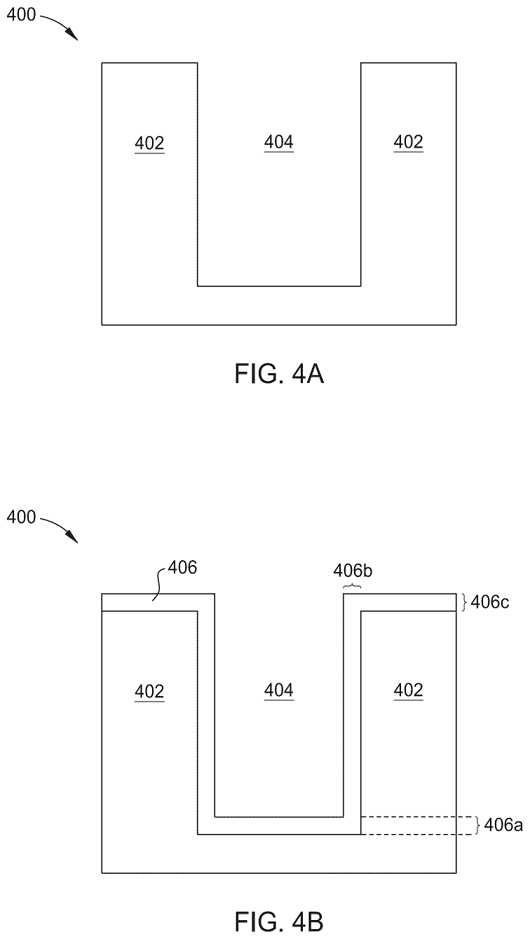

FIG. 3 is a flow chart illustrating a method 300 of forming an epitaxial layer in accordance with one or more aspects of the present disclosure. FIG. 4A and FIG. 4B are schematic cross-section diagrams of a substrate 400 both before and after undergoing the method 300, respectively. At operation 302, a substrate, for example the substrate 400, is positioned within a processing chamber. More specifically, at operation 302, a substrate is positioned in the processing volume of the processing chamber. The processing chamber may be a CENTURA® RP Epi chamber available from Applied Materials, Inc., of Santa Clara, California. It is contemplated that other chambers, including those available from other manufacturers, may be used to practice aspects of the disclosure.

The term “substrate” is intended to broadly cover any article or material having a surface onto which a material layer can be deposited. A substrate may include a bulk material 402 such as silicon (e.g., single crystal silicon which may include dopants) or may include one or more layers overlying the bulk material. The substrate may be a planar substrate or a patterned substrate. Patterned substrates, such as the substrate 400, are substrates that may include electronic features 404 formed into or onto a processing surface of the substrate. The substrate may contain monocrystalline surfaces and/or one secondary surface that is non-monocrystalline, such as polycrystalline or amorphous surfaces. Monocrystalline surfaces may include the bare crystalline substrate or a deposited single crystal layer usually made from a material such as silicon, germanium, silicon germanium, or silicon carbon. Polycrystalline or amorphous surfaces may include dielectric materials, such as oxides or nitrides, specifically silicon oxide or silicon nitride, as well as amorphous silicon surfaces. The substrate may have various dimensions, such as 200 mm, 300 mm, 450 mm, or another diameter, as well as, being a rectangular or square panel. Unless otherwise noted, examples described are conducted on substrates with a 200 mm diameter, a 300 mm diameter, or a 450 mm diameter substrate.

In at least one aspect, the substrate includes a first surface and a second surface different from the first surface. At least one of the first surface and the second surface is monocrystalline and the other surface is non-monocrystalline. Positioning the substrate in the processing chamber may include adjusting one or more reactor conditions, such as temperature, pressure, and/or carrier gas (e.g., Ar, N₂, H₂, or He) flow rate, to conditions suitable for epitaxial film formation.

It has been shown that the growth rate of the epitaxial layer with respect to the exposed crystalline surfaces of the superlattice structure changes with the addition of different concentrations of phosphorus in the epitaxial layer. In some aspects described herein, the concentration of phosphorus in the epitaxial layer is greater than about 1×10²¹ atoms/cm³ and growth is primarily in the <100> direction. The phosphorus concentration has been shown to cause the predominant crystal growth in the <110> direction. The crystal growth primarily in the <100> direction reduces faceting of the epitaxial layer on the superlattice structure.

At operation 304, the substrate and/or the processing volume of the processing chamber is heated to a temperature of about 500° C. or less, such as about 450° C. or less, such as about 400° C. or less. In at least one aspect, the temperature in the processing chamber may be adjusted so that a reaction region formed at or near an exposed surface of the substrate, or that the surface of the substrate itself, is about 490° C. or less, such as about 480° C. or less, such as about 450° C. or less. In one example, the substrate is heated to a temperature in a range from 200° C. to about 1100° C., such as about 400° C. to about 800° C., such as about 500° C. to about 700° C., alternatively about 200° C. to about 400° C., alternatively about 400° C. to about 500° C., alternatively about 500° C. to about 600° C., alternatively about 600° C. to about 700° C., alternatively about 700° C. to about 800° C., alternatively about 800° C. to about 1100° C. As previously discussed, conventional processes for epitaxial deposition of Si:P layers onto a substrate at temperatures below 450° C. have low growth rates, if any formation occurs at all. Furthermore, conventional processes for epitaxial deposition of Si:P layers onto a substrate at temperatures greater than 550° C. may affect the thermal budget of other materials formed on the substrate. The epitaxial deposition processes disclosed herein differ from, and may be advantageous over, conventional processes by utilizing increased process gas pressures within the processing chamber to enable low temperature epitaxial Si:P deposition.

The pressure in the processing chamber may be adjusted to be within a range of about 10 Torr to about 600 Torr, such as about 50 Torr to about 400 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 400 Torr, alternatively about 400 Torr to about 600 Torr. In some implementations, a carrier gas (e.g., nitrogen) may be flowed into the processing chamber at a flow rate of approximately 0.01 to 40 standard liters per minute (SLM), such as about 0.1 SLM to about 30 SLM, such as about 1 SLM to about 20 SLM, such as about 5 SLM to about 10 SLM, alternatively about 0.01 SLM to about 0.1 SLM, alternatively about 0.1 SLM to about 1 SLM, alternatively about 1 SLM to about 5 SLM, alternatively about 10 SLM to about 20 SLM, alternatively about 20 SLM to about 30 SLM, alternatively about 30 SLM to about 40 SLM. Nitrogen remains inert during low temperature deposition processes. Therefore, nitrogen is not incorporated into the deposited layer during low temperature processes. Also, while a hydrogen carrier gas forms hydrogen-terminated surfaces, a nitrogen carrier gas does not passivate surface bonds and thus does not form nitrogen-terminated surfaces. However, it will be appreciated that in some implementations, a different carrier/diluent gas may be employed (e.g., an inert carrier gas such as argon or helium), a different flow rate may be used, or that such gas(es) may be omitted. Once the processing chamber has reached suitable processing conditions, a processing gas having one or more of a silicon source, a dopant gas, and/or a carrier gas may be introduced into the processing chamber.

At operation 306, a silicon source is introduced to the processing volume of the processing chamber. In some embodiments, the silicon source is introduced to the processing chamber such that the silicon source is present in the processing volume at a partial pressure of about 10 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

In some embodiments, the process gas includes one or more deposition gases and at least one dopant gas. The deposition gas may include one or more precursor gases selected from Group III precursor gas, Group V precursor gas, Group VI precursor gas, or Group IV precursor gas. In cases where a silicon-containing epitaxial layer is formed, the deposition gas may contain at least a silicon source (e.g., a silicon source gas). Exemplary silicon sources may include, but are not limited to, silanes, halogenated silanes, silicon tetrachloride (SiCl₄), or any combinations thereof. Silanes may include silane (SiH₄) and higher silanes with the empirical formula SiₓH(₂ₓ₊₂), such as disilane (Si₂H₆), trisilane (Si₃H₈), tetrasilane (Si₄H₁₀), pentasilane (Si₅H₁₂), or hexasilane (Si₆H₁₄). Other higher silanes, such as a silicon hydride expressed as SiₙH₂ₙ (n is a natural number equal to or greater than 3), may also be used. For example, cyclotrisilane (Si₃H₆), cyclotetrasilane (Si₄H₈), cyclopentasilane (Si₆H₁₀), cyclohexasilane (Si₆H₁₂), or cycloheptasilane (Si₇H₁₄). Halogenated silanes may include monochlorosilane (MCS), dichlorosilane (DCS), trichlorosilane (TCS), hexachlorodisilane (HCDS), octachlorotrisilane (OCTS), silicon tetrachloride (STC), or a combination thereof. In some implementations, silanes may include higher order silanes with varying degrees of halogenation in the form of —F, Cl, Br, or I attached to them in order to enable selectivity. For example, Si₂H₄Cl₂ or Si₃H₅Cl₃ etc.

In one exemplary embodiment, the silicon source comprises tetrasilane. In another exemplary embodiment, the silicon source comprises disilane. In yet another exemplary embodiment, the silicon source comprises tetrasilane and disilane.

At operation 308, a dopant gas is introduced to the processing volume of the processing chamber. In some embodiments, the dopant gas is introduced to the processing chamber such that the dopant gas is present in the processing volume at a partial pressure of about 10 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

The dopant gas may include one or more compounds including phosphorous, boron, arsenic, gallium, or aluminum, depending on the desired conductive characteristic of the deposited epitaxial layer. The deposition gas may optionally contain at least one secondary elemental source, such as a germanium source or a carbon source. Depending on application, other elements, such as metals, halogens, or hydrogen may be incorporated within a silicon-containing layer. In some implementations, the silicon-containing epitaxial layer is phosphorous doped silicon (Si:P), which can be achieved using a dopant such as phosphine (PH₃), phosphorus trichloride (PCl₃), phosphorous tribromide (PBr₃), and phosphates such as tributyl phosphate (TBP).

Operations 306 and 308 may be conducted sequentially or simultaneously. In the case of sequential operations, the silicon source and dopant gas may be introduced to the processing chamber in any suitable order (e.g., silicon source then dopant gas or dopant gas then silicon source). For the sake of brevity, the silicon source, the dopant gas, or both being introduced to the processing chamber may, in some embodiments, be referred to as the “process gas”and/or “processing reagents”.

The processing reagents (e.g., the silicon source and the dopant gas) may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. Nitrogen may be utilized as a carrier gas in implementations featuring low temperature (e.g., <600° C.) processes. The carrier gas may have a flow rate from about 1 SLM to about 35 SLM, such as from about 3 SLM to about 30 SLM, such as about 10 SLM to about 20 SLM, alternatively about 1 SLM to about 3 SLM, alternatively about 3 SLM to about 10 SLM, alternatively about 10 SLM to about 15 SLM, alternatively about 15 SLM to about 20 SLM, alternatively about 20 SLM to about 30 SLM, alternatively about 30 SLM to about 35 SLM.

In some embodiments, the silicon source gas may be flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In some embodiments, the dopant gas may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of the silicon source gas relative to the dopant gas is about 0.1:1 to about 1:1, such as about 0.5:1 to about 1:1, such as about 0.8:1 to about 1:1.

In at least one embodiment, the silicon source gas includes disilane and is flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the dopant gas includes a phosphorus-containing compound (e.g., phosphine). The phosphorus-containing compound may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of silicon atoms relative to phosphorus atoms within the process gas is about 0.1:1 to about 1:1, such as about 0.5:1 to about 1:1, such as about 0.8:1 to about 1:1.

At operation 310, an epitaxial layer (e.g., a crystalline Si:P layer) is deposited onto the surface of the substrate as illustrated in FIG. 4B. FIG. 4B shows a schematic cross-section diagram of a substrate 400 which has undergone the epitaxial deposition process of the method 300, wherein an epitaxial layer 406 (e.g., a crystalline Si:P layer) is deposited onto the surface of bulk material 402 and within the feature 404 of the substrate 400. The epitaxial layer (e.g., a crystalline Si:P layer) exhibits a crystalline growth rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min. In some embodiments, the epitaxial layer (e.g., the crystalline Si:P layer) has a thickness of about 1 nm to about 100 nm, such as about 20 nm to about 80 nm, such as about 40 nm to about 60 nm, alternatively about 1 nm to about 20 nm, alternatively about 20 nm to about 40 nm, alternatively about 60 nm to about 80 nm, alternatively about 80 nm to about 100 nm.

In some embodiments, the substrate 400 may include a feature 404 on its surface, such as a trench as shown in FIG. 4B. In which case the deposited crystalline epitaxial growth layer 406 (e.g., the crystalline Si:P layer) may have a layer thickness at the bottom of the feature 406a, the side wall of the feature 406b, and on the top surface of the feature 406c. The layer thickness at the bottom of the feature 406a may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The layer thickness on the side wall of the feature 406b may be from about 5 nm to about 30 nm, such as about 10 nm to about 25 nm, such as about 15 nm to about 20 nm, alternatively about 5 nm to about 10 nm, alternatively about 10 nm to about 15 nm, alternatively about 20 nm to about 25 nm, alternatively about 25 nm to about 30 nm. The layer thickness on the top surface of the feature 406c may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

In some embodiments, the crystalline epitaxial layer has a dopant concentration of about 1×10²⁰ atom/cm³ to about 5×10²¹ atom/cm³, such as about 5×10²⁰ atom/cm³ to about 1×10²¹ atom/cm³. In at least one embodiment, the crystalline epitaxial layer is a crystalline Si:P layer having a phosphorus concentration of about 1×10²⁰ atom/cm³ to about 5×10²¹ atom/cm³, such as about 5×10²⁰ atom/cm³ to about 1×10²¹ atom/cm³. In one or more embodiments, the crystalline epitaxial layer (e.g., the crystalline Si:P layer) has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

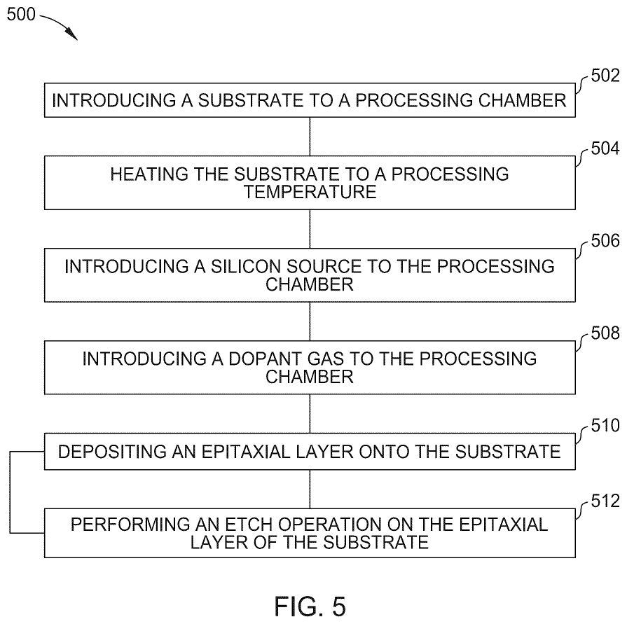

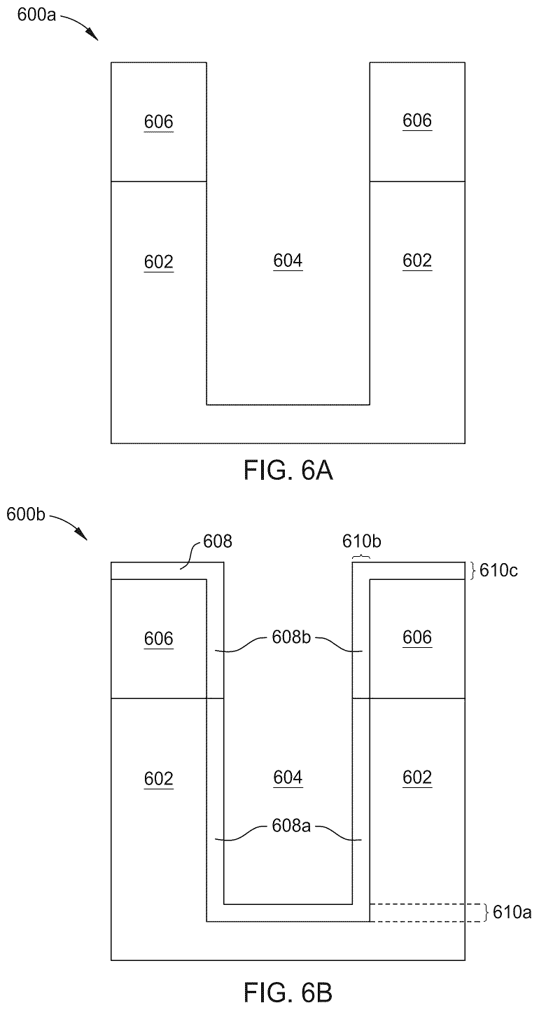

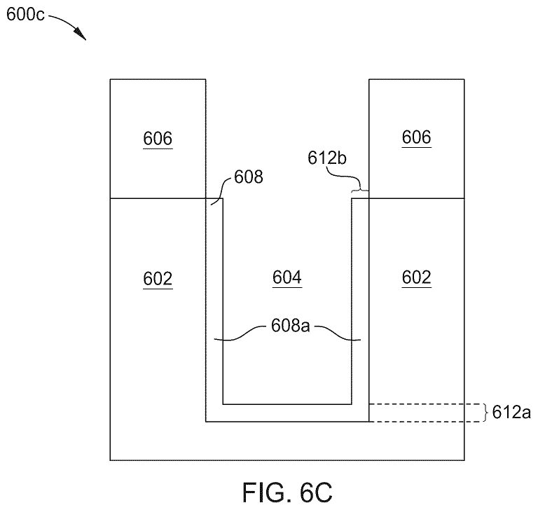

FIG. 5 is a flow chart illustrating a method 500 of forming an epitaxial layer in accordance with one or more aspects of the present disclosure. At operation 502, a substrate, for example the substrate 600a of FIG. 6A, is positioned within a processing chamber. More specifically, at operation 502 a substrate is positioned in the processing volume of the processing chamber. The substrate, such as the substrate 600, may contain one or more monocrystalline material layers and surfaces thereof. Additionally or alternatively, the substrate may include a second layer 606 and surfaces thereof composed of one or more secondary material layers. The one or more secondary material layers may include one or more materials that are not monocrystalline, such as polycrystalline or amorphous surfaces. The substrate may also include one or more features deposited on or in the surface of the substrate. Monocrystalline surfaces of the monocrystalline material layer may include the bare crystalline substrate or a deposited single crystal layer usually made from a material such as silicon, germanium, silicon germanium, or silicon carbon. Polycrystalline or amorphous surfaces may include dielectric materials, such as oxides or nitrides, specifically silicon oxide or silicon nitride, as well as amorphous silicon surfaces. It is understood that the substrate may include multiple layers, and/or may include, for example, partially fabricated devices such as transistors, flash memory devices, and the like.

In at least one embodiment, the substrate positioned within the processing chamber can be represented by the substrate 600a shown in FIG. 6A. The substrate 600a can include a first layer 602 and a second layer 606 disposed over the first layer 602. The substrate 600a can also include one or more features 604 disposed on or within the surface of the substrate, such as the trench shown in FIG. 6A. In one example, the second layer 606 is a partial representation of a contact structure. The first layer 602 may include a monocrystalline surface, such as silicon or silicon carbide. The second layer 606 may include a polycrystalline or amorphous surface, such as silicon oxide or silicon nitride.

At operation 504, the substrate and/or the processing volume of the processing chamber is heated to a temperature of 450° C. or less. In at least one aspect, the temperature in the processing chamber may be adjusted so that a reaction region formed at or near an exposed surface of the substrate, or the surface of the substrate itself, is about 450° C. or less. In one example, the substrate is heated to a temperature in a range from about 200° C. to about 450° C., such as about 250° C. to about 400° C., such as about 300° C. to about 350° C., alternatively about 200° C. to about 250° C., alternatively about 250° C. to about 300° C., alternatively about 350° C. to about 400° C., alternatively about 400° C. to about 450° C.

At operation 506, a silicon source is introduced to the processing volume of the processing chamber. In some embodiments, the silicon source is introduced to the processing chamber such that the silicon source is present in the processing volume at a partial pressure of about 10 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

In some embodiments, the process gas includes one or more deposition gases and at least one dopant gas. The deposition gas may include one or more precursor gases selected from Group III precursor gas, Group V precursor gas, Group VI precursor gas, or Group IV precursor gas. In cases where a silicon-containing epitaxial layer is formed, the deposition gas may contain at least a silicon source (e.g., a silicon source gas). Exemplary silicon sources may include, but are not limited to, silanes, halogenated silanes, silicon tetrachloride (SiCl₄), or any combinations thereof. Silanes may include silane (SiH₄) and higher silanes with the empirical formula SiₓH(₂ₓ₊₂), such as disilane (Si₂H₆), trisilane (Si₃H₈), tetrasilane (Si₄H₁₀), pentasilane (Si₅H₁₂), or hexasilane (Si₆H₁₄). Other higher silanes, such as a silicon hydride expressed as SiₙH₂ₙ (n is a natural number equal to or greater than 3), may also be used. For example, cyclotrisilane (Si₃H₆), cyclotetrasilane (Si₄H₈), cyclopentasilane (Si₆H₁₀), cyclohexasilane (Si₆H₁₂), or cycloheptasilane (Si₇H₁₄). Halogenated silanes may include monochlorosilane (MCS), dichlorosilane (DCS), trichlorosilane (TCS), hexachlorodisilane (HCDS), octachlorotrisilane (OCTS), silicon tetrachloride (STC), or a combination thereof. In some implementations, silanes may include higher order silanes with varying degrees of halogenation in the form of —F, Cl, Br, or I attached to them in order to enable selectivity. For example, Si₂H₄Cl₂ or Si₃H₅Cl₃ etc.

In one exemplary embodiment, the silicon source comprises tetrasilane. In another exemplary embodiment, the silicon source comprises disilane. In yet another exemplary embodiment, the silicon source comprises tetrasilane and disilane.

At operation 508, a dopant gas is introduced to the processing volume of the processing chamber. In some embodiments, the dopant gas is introduced to the processing chamber such that the dopant gas is present in the processing volume at a partial pressure of about 5 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

The dopant gas may include one or more compounds including phosphorous, boron, arsenic, gallium, or aluminum, depending on the desired conductive characteristic of the deposited epitaxial layer. The deposition gas may optionally contain at least one secondary elemental source, such as a germanium source or a carbon source. Depending on application, other elements, such as metals, halogens or hydrogen may be incorporated within a silicon-containing layer. In one exemplary implementation, the silicon-containing epitaxial layer is phosphorous doped silicon (Si:P), which can be achieved using a dopant such as phosphine (PH₃), phosphorus trichloride (PCl₃), phosphorous tribromide (PBr₃), and phosphates such as tributyl phosphate (TBP).

Operations 506 and 508 may be conducted sequentially or simultaneously. In the case of sequential operations, the silicon source and dopant gas may be introduced to the processing chamber in any suitable order (e.g., silicon source then dopant gas or dopant gas then silicon source). For the sake of brevity, the silicon source, the dopant gas, or both being introduced to the processing chamber may, in some embodiments, be referred to as the “process gas” and/or “processing reagents”.

The processing reagents (e.g., the silicon source and the dopant gas) may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. Nitrogen may be utilized as a carrier gas in implementations featuring low temperature (e.g., <600° C.) processes. The carrier gas may have a flow rate from about 1 SLM to about 100 SLM, such as from about 3 SLM to about 30 SLM, such as about 10 SLM to about 20 SLM, alternatively about 1 SLM to about 3 SLM, alternatively about 3 SLM to about 10 SLM, alternatively about 10 SLM to about 15 SLM, alternatively about 15 SLM to about 20 SLM, alternatively about 20 SLM to about 30 SLM, alternatively about 30 SLM to about 35 SLM.

In some embodiments, the silicon source gas may be flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In some embodiments, the dopant gas may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of the silicon source gas relative to the dopant gas is about 1:1 to about 100:1, such as about 1:1 to about 50:1, such as about 1:1 to about 25:1.

In at least one embodiment, the silicon source gas includes disilane and is flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the dopant gas includes a phosphorus-containing compound (e.g., phosphine). The phosphorus-containing compound may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of silicon atoms relative to phosphorus atoms within the process gas is about 1:1 to about 100:1, such as about 1:1 to about 50:1, such as about 1:1 to about 25:1.

At operation 510, an epitaxial layer (e.g., a Si:P layer) is deposited onto the surface of the substrate, as illustrated in FIG. 6B. FIG. 6B shows a schematic cross-sectional diagram of a substrate 600b having an epitaxial layer 608 disposed thereon. The epitaxial layer 608 includes a crystalline portion 608a disposed over the surface of the first layer 602 and an amorphous portion 608b disposed over the surface of the second layer 606. Additionally, the epitaxial layer 608 is deposited within and/or onto the surface of a feature 604 of the substrate 600b. In some embodiments, the epitaxial layer (e.g., a Si:P layer) is deposited at a deposition rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min. In one or more embodiments, epitaxial layer (e.g., a Si:P layer) exhibits a crystalline growth rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min.

In some embodiments, the substrate 600b may include a feature 604 on its surface, such as a trench as shown in FIG. 6B. In which case, the deposited epitaxial layer 608 (e.g., the crystalline Si:P layer) may have a layer thickness 610a at the bottom of the feature, a layer thickness 610b on the sidewall of the feature, and a layer thickness 610c on the top surface of the feature. The layer thickness 610a at the bottom of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The layer thickness 610b on the sidewall of the feature may be from about 5 nm to about 30 nm, such as about 10 nm to about 25 nm, such as about 15 nm to about 20 nm, alternatively about 5 nm to about 10 nm, alternatively about 10 nm to about 15 nm, alternatively about 20 nm to about 25 nm, alternatively about 25 nm to about 30 nm. The layer thickness 610c on the top surface of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

In some embodiments, the epitaxial layer has a dopant concentration of about 1×10²⁰ atom/cm³ to about 5×10²¹ atom/cm³, such as about 5×10²⁰ atom/cm³ to about 1×10²¹ atom/cm³. In at least one embodiment, the epitaxial layer is a crystalline Si:P layer having a phosphorus concentration of about 1×10²⁰ atom/cm³ to about 5×10²¹ atom/cm³, such as about 5×10²⁰ atom/cm³ to about 1×10²¹ atom/cm³. In one or more embodiments, the crystalline epitaxial layer (e.g., the crystalline Si:P layer) has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

At operation 512, the epitaxial layer (e.g., a crystalline Si:P layer) is subjected to an etch process, such as a selective etch process, to produce a processed substrate 600c as shown in FIG. 6C. FIG. 6C shows a processed substrate 600c produced via the method 500, wherein the amorphous portion 608b of the epitaxial layer 608 of substrate 600b is substantially etched from the surface of the second layer 606. The processed substrate 600c includes the crystalline portion 608a of the epitaxial layer 608 disposed over the surface of the first layer 602. In at least one embodiment, the processed substrate 600c includes a feature 604, such as a trench, configured such that the crystalline portion 608a of the epitaxial layer 608 disposed within the feature 604 has a layer thickness 612a of about 5 nm to about 50 nm at the bottom of the feature, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The crystalline portion 608a of the epitaxial layer 608 disposed within the feature 604 has layer thickness 612b about 5 nm to about 50 nm on the side wall of the feature, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

The etchant process (e.g., a chemical etch process) may include introducing an etchant to the processing chamber via an etchant gas. The etchant gas may include at least one etchant and a carrier gas. The etchant may be a halogen-containing etchant. Exemplary etchants may include, but are not limited to hydrogen chloride (HCl), germanium hydride (GeH₄), chlorine (Cl₂), boron trichloride (BCl₃), phosphorus trichloride (PCl₃), or any combinations thereof. Higher order germanes such as digermane (Ge₂H₆), or chlorinated germane gas such as germanium tetrachloride (GeCl₄), dichlorogermane (GeH₂Cl₂), or a combination of any two or more thereof, may also be used. In one implementation, the etchant includes HCl and GeH₄. In another implementation, the etchant includes HCl and PCl₃. In yet another implementation, the etchant includes Cl₂ and PCl₃. In yet one another implementation, the etchant includes HCl, GeH₄, and PCl₃. Any suitable halogenated germanium compounds may also be used. In at least one embodiment, the etchant gas includes HCl. In at least one embodiment, the etchant gas includes a carrier gas. The carrier gas may include hydrogen, nitrogen, argon, helium, and any combinations thereof. A carrier gas may be selected based upon specific etchant(s).

In at least one embodiment, the etchant includes HCl and GeH₄. In another embodiment, the etchant includes Cl₂ and GeH₄. In cases where HCl and GeH₄ are used during etching, the flow of HCl and GeH₄ may be introduced into the epitaxy chamber at a GeH₄/HCl ratio of about 1:3 to about 1:7, for example about 1:5. In one exemplary example, GeH₄ is introduced at a flow rate of about 60 sccm and HCl is introduced at 300 sccm, with the carrier gas (N₂) introduced at a flow rate of about 3 SLM.

During operation 512, the etchant gas is introduced to the processing chamber at a rate of about 10 sccm to about 1000 sccm, such as about 50 sccm to about 800 sccm, such as about 100 sccm to about 600 sccm, such as about 200 sccm to about 400 sccm, alternatively about 10 sccm to about 50 sccm, alternatively about 50 sccm to about 100 sccm, alternatively about 100 sccm to about 200 sccm, alternatively about 200 sccm to about 300 sccm, alternatively about 300 sccm to about 400 sccm, alternatively about 400 sccm to about 600 sccm, alternatively about 600 sccm to about 800 sccm, alternatively about 800 sccm to about 1000 sccm. The pressure within the processing chamber is maintained at about 10 Torr to about 600 Torr, such as about 100 Torr to about 500 Torr, such as about 200 Torr to about 400 Torr, alternatively about 10 Torr to about 100 Torr, alternatively about 100 Torr to about 200 Torr, alternatively about 200 Torr to about 300 Torr, alternatively about 300 Torr to about 400 Torr, alternatively about 400 Torr to about 500 Torr, alternatively about 500 Torr to about 600 Torr. The temperature within the processing chamber is maintained at about 300° C. to about 600° C., such as about 350° C. to about 550° C., such as about 400° C. to about 500° C., alternatively about 300° C. to about 350° C., alternatively about 350° C. to about 400° C., alternatively about 400° C. to about 450° C., alternatively about 450° C. to about 500° C., alternatively about 500° C. to about 550° C., alternatively about 550° C. to about 600° C. The etching process is performed for an etch time of about 10 seconds(s) to about 1000 s, such as about 100 s to about 800 s, such as about 400 s to about 600 s, alternatively about 10 s to about 100 s, alternatively about 100 s to about 400 s, alternatively about 400 s to about 500 s, alternatively about 500 s to about 600 s, alternatively about 600 s to about 800 s, alternatively about 800 s to about 1000 s.

In at least one embodiment, the etch process is a selective etch process. The selective etch process selectively removes the amorphous portion (e.g., 608b of FIG. 6B) of the epitaxial layer from the surface of the substrate, leaving only the crystalline portion 608a of the epitaxial layer 608, as shown in FIG. 6C. In some embodiments, the etch process removes the amorphous portion of the epitaxial layer at an etch rate of about 0.5 Å/min to about 50 Å/min, such as about 1 Å/min to about 40 Å/min, such as about 10 Å/min to about 30 Å/min, alternatively about 0.5 Å/min to about 1 Å/min, alternatively about 1 Å/min to about 10 Å/min, alternatively about 10 Å/min to about 20 Å/min, alternatively about 20 Å/min to about 30 Å/min, alternatively about 30 Å/min to about 40 Å/min, alternatively about 40 Å/min to about 50 Å/min. In some embodiments, the etch process removes the crystalline portion of the epitaxial layer at an etch rate of 20 Å/min or less, such as about 10 Å/min or less, such as about 5 Å/min or less, such as about 1 Å/min or less, such as about 0.5 Å/min or less.

In at least one embodiment, the etch process is a plasma etch process. The plasma etch process may be performed in the epitaxial deposition chamber or a different chamber configured to provide a plasma to the surface of the substrate. In at least one embodiment, the plasma source is a remote plasma source. In some embodiments that implement a remote plasma source, excitation of the gas species allows plasma damage-free substrate processing. The remote plasma etch can be largely conformal and selective towards silicon oxide layers, and thus does not readily etch silicon regardless of whether the silicon is amorphous, crystalline, or polycrystalline. The remote plasma process will generally produce solid by-products which grow on the surface of the substrate as substrate material is removed. The solid by-products can be subsequently removed via sublimation when the temperature of the substrate is raised (e.g., 300° C.). The plasma etch process results in a substrate surface having silicon-hydrogen (Si—H) bonds thereon.

In some embodiments, the plasma etch process is performed at a pressure of about 1 mTorr to about 500 mTorr, such as about 50 mTorr to about 400 mTorr, such as about 100 mTorr to about 300 mTorr, alternatively about 1 mTorr to about 50 mTorr, alternatively about 50 mTorr to about 100 mTorr, alternatively about 100 mTorr to about 200 mTorr, alternatively about 200 mTorr to about 300 mTorr, alternatively about 300 mTorr to about 400 mTorr, alternatively about 400 mTorr to about 500 mTorr. The plasma etch process may be performed at a processing temperature of about 50° C. to about 500° C., such as about 100° C. to about 400° C., such as about 200° C. to about 300° C., alternatively about 50° C. to about 100° C., alternatively about 100° C. to about 200° C., alternatively about 300° C. to about 400° C., alternatively about 400° C. to about 500° C. In some embodiments, the etch process removes the amorphous portion of the epitaxial layer at an etch rate of about 0.5 Å/min to about 50 Å/min, such as about 1 Å/min to about 40 Å/min, such as about 10 Å/min to about 30 Å/min, alternatively about 0.5 Å/min to about 1 Å/min, alternatively about 1 Å/min to about 10 Å/min, alternatively about 10 Å/min to about 20 Å/min, alternatively about 20 Å/min to about 30 Å/min, alternatively about 30 Å/min to about 40 Å/min, alternatively about 40 Å/min to about 50 Å/min. In some embodiments, the etch process removes the crystalline portion of the epitaxial layer at an etch rate of 20 Å/min or less, such as about 10 Å/min or less, such as about 5 Å/min or less, such as about 1 Å/min or less, such as about 0.5 Å/min or less.

In some embodiments, the etch process exhibits an amorphous silicon/crystalline epitaxial layer etch selectivity. Thus, the result is a thinner amorphous silicon layer on the dielectric surface compared to the epitaxial layer on the semiconductor surface due to the selectivity of the etch process.

In some embodiments, the deposition process of operation 510 and the etching process of operation 512 may be cyclically performed until a crystalline epitaxial layer of significant thickness is deposited onto the surface of the substrate. In at least one embodiment, operations 510 and 512 may be concurrently performed. In at least one embodiment, operations 510 and 512 may be cyclically performed and/or repeated for 1 cycle to 100 cycles, such as 10 cycles to 90 cycles, such as 25 cycles to 75 cycles, alternatively 1 cycle to 10 cycles, alternatively 10 cycles to 25 cycles, alternatively 25 cycles to 50 cycles, alternatively 50 cycles to 75 cycles, alternatively 75 cycles to 100 cycles. In such embodiments, the deposited crystalline epitaxial layer (e.g., the crystalline Si:P layer) may have a layer thickness 612a at the bottom of the feature and a layer thickness 612b on the side wall of the feature adjacent to the monocrystalline layer (e.g., first layer 602) of the substrate. The layer thickness 612a at the bottom of the feature may be from about 1 nm to about 100 nm, such as about 20 nm to about 80 nm, such as about 40 nm to about 60 nm, alternatively about 1 nm to about 20 nm, alternatively about 20 nm to about 40 nm, alternatively about 40 nm to about 50 nm, alternatively about 50 nm to about 60 nm, alternatively about 60 nm to about 80 nm, alternatively about 80 nm to about 100 nm. The layer thickness 612b on the sidewall of the feature may be from about 1 nm to about 100 nm, such as about 20 nm to about 80 nm, such as about 40 nm to about 60 nm, alternatively about 1 nm to about 20 nm, alternatively about 20 nm to about 40 nm, alternatively about 40 nm to about 50 nm, alternatively about 50 nm to about 60 nm, alternatively about 60 nm to about 80 nm, alternatively about 80 nm to about 100 nm.

In at least one embodiment, the etch process of operation 512 does not completely remove the amorphous portion 608b of the epitaxial layer 608 from the substrate 600b. In such embodiments, the remaining amorphous portion 608b of the epitaxial layer 608 of the substrate 600b has a layer thickness 610b on the sidewall of the feature of about 1 nm to about 100 nm, such as about 20 nm to about 80 nm, such as about 40 nm to about 60 nm, alternatively about 1 nm to about 20 nm, alternatively about 20 nm to about 40 nm, alternatively about 40 nm to about 50 nm, alternatively about 50 nm to about 60 nm, alternatively about 60 nm to about 80 nm, alternatively about 80 nm to about 100 nm. In at least one embodiment, the remaining amorphous portion 608b of the epitaxial layer 608 of the substrate 600b has a layer thickness 610c on the top surface of the feature of about 1 nm to about 100 nm, such as about 20 nm to about 80 nm, such as about 40 nm to about 60 nm, alternatively about 1 nm to about 20 nm, alternatively about 20 nm to about 40 nm, alternatively about 40 nm to about 50 nm, alternatively about 50 nm to about 60 nm, alternatively about 60 nm to about 80 nm, alternatively about 80 nm to about 100 nm.

In some embodiments, epitaxial films formed by a method disclosed herein, such as the method 300 and/or the method 500, have a dopant concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In at least one embodiment, the epitaxial film formed by the method 500 is a crystalline Si:P layer having a phosphorus concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In one or more embodiments, the crystalline epitaxial layer (e.g., the crystalline Si:P layer) has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

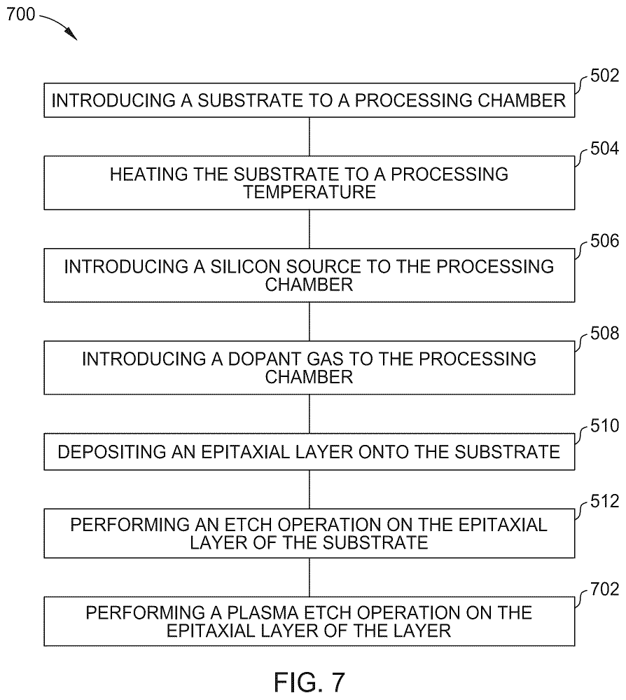

FIG. 7 is a flow chart illustrating a method 700 of forming an epitaxial layer in accordance with one or more aspects of the present disclosure. Similar to the method 500, the method 700 includes introducing a substrate (e.g., the substrate 600a of FIG. 6A) to a processing chamber (operation 502). The method 700 may also include heating the substrate and/or the processing volume of the processing chamber to a processing temperature (operation 504). The substrate and/or the processing volume of the processing chamber may be heated to a temperature of 450° C. or less. In at least one aspect, the temperature in the processing chamber may be adjusted so that a reaction region formed at or near an exposed surface of the substrate, or the surface of the substrate itself, is about 450° C. or less. In one example, the substrate is heated to a temperature in a range from about 200° C. to about 450° C., such as about 250° C. to about 400° C., such as about 300° C. to about 350° C., alternatively about 200° C. to about 250° C., alternatively about 250° C. to about 300° C., alternatively about 350° C. to about 400° C., alternatively about 400° C. to about 450° C.

In some embodiments, the method 700 includes introducing a silicon source (operation 506) and/or a dopant gas (operation 508), either sequentially or simultaneously, into the processing volume of the processing chamber. In some embodiments, the silicon source is introduced to the processing chamber via a process gas such that the silicon source is present in the processing volume at a partial pressure of about 10 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

In some embodiments, the process gas includes one or more deposition gases and at least one dopant gas. The deposition gas may include one or more precursor gases selected from Group III precursor gas, Group V precursor gas, Group VI precursor gas, or Group IV precursor gas. In cases where a silicon-containing epitaxial layer is formed, the deposition gas may contain at least a silicon source (e.g., a silicon source gas). Exemplary silicon sources may include, but are not limited to, silanes, halogenated silanes, silicon tetrachloride (SiCl₄), or any combinations thereof. Silanes may include silane (SiH₄) and higher silanes with the empirical formula SiₓH(₂ₓ₊₂), such as disilane (Si₂H₆), trisilane (Si₃H₈), tetrasilane (Si₄H₁₀), pentasilane (Si₅H₁₂), or hexasilane (Si₆H₁₄). Other higher silanes, such as a silicon hydride expressed as SiₙH₂ₙ (n is a natural number equal to or greater than 3), may also be used. For example, cyclotrisilane (Si ₃H₆), cyclotetrasilane (Si₄H₈), cyclopentasilane (Si₆H₁₀), cyclohexasilane (Si₆H₁₂), or cycloheptasilane (Si₇H₁₄). Halogenated silanes may include monochlorosilane (MCS), dichlorosilane (DCS), trichlorosilane (TCS), hexachlorodisilane (HCDS), octachlorotrisilane (OCTS), silicon tetrachloride (STC), or a combination thereof. In some implementations, silanes may include higher order silanes with varying degrees of halogenation in the form of —F, Cl, Br, or I attached to them in order to enable selectivity. For example, Si₂H₄Cl₂ or Si₃H₅Cl₃ etc.

In one exemplary embodiment, the silicon source comprises tetrasilane. In another exemplary embodiment, the silicon source comprises disilane. In yet another exemplary embodiment, the silicon source comprises tetrasilane and disilane.

In some embodiments, the dopant gas is introduced to the processing chamber via a process gas such that the dopant gas is present in the processing volume at a partial pressure of about 5 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

The dopant gas may include one or more compounds including phosphorous, boron, arsenic, gallium, or aluminum, depending on the desired conductive characteristic of the deposited epitaxial layer. The deposition gas may optionally contain at least one secondary elemental source, such as a germanium source or a carbon source. Depending on application, other elements, such as metals, halogens or hydrogen may be incorporated within a silicon-containing layer. In one exemplary implementation, the silicon-containing epitaxial layer is phosphorous doped silicon (Si:P), which can be achieved using a dopant such as phosphine (PH₃), phosphorus trichloride (PCl₃), phosphorous tribromide (PBr₃), and phosphates such as tributyl phosphate (TBP).

The silicon source and dopant gas may be introduced to the processing chamber in any suitable order (e.g., silicon source then dopant gas or dopant gas then silicon source). As previously described, the silicon source, the dopant gas, or both being introduced to the processing chamber may, in some embodiments, be referred to as the “process gas”and/or “processing reagents”.

The processing reagents (e.g., the silicon source and the dopant gas) may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. Nitrogen may be utilized as a carrier gas in implementations featuring low temperature (e.g., <600° C.) processes. The carrier gas may have a flow rate from about 1 SLM to about 100 SLM, such as from about 3 SLM to about 30 SLM, such as about 10 SLM to about 20 SLM, alternatively about 1 SLM to about 3 SLM, alternatively about 3 SLM to about 10 SLM, alternatively about 10 SLM to about 15 SLM, alternatively about 15 SLM to about 20 SLM, alternatively about 20 SLM to about 30 SLM, alternatively about 30 SLM to about 35 SLM.

In some embodiments, the silicon source gas may be flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In some embodiments, the dopant gas may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of the silicon source gas relative to the dopant gas is about 1:1 to about 100:1, such as about 1:1 to about 50:1, such as about 1:1 to about 25:1.

In at least one embodiment, the silicon source gas includes disilane and is flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the dopant gas includes a phosphorus-containing compound (e.g., phosphine). The phosphorus-containing compound may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of silicon atoms relative to phosphorus atoms within the process gas is about 1:1 to about 100:1, such as about 1:1 to about 50:1, such as about 1:1 to about 25:1.

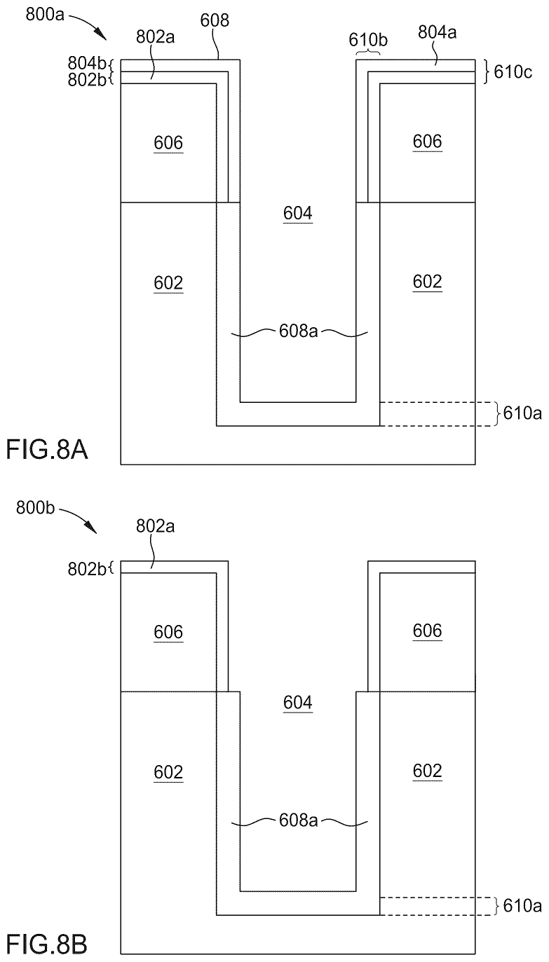

The method 700 may also include depositing an epitaxial layer 608 onto the surface of the substrate (operation 510), as illustrated by the substrate 800a shown in FIG. 8A. In some embodiments, the epitaxial layer 608 includes a crystalline portion 608a disposed over a surface of the first layer 602, a phosphosilicate portion 802a disposed over the surface of the second layer 606, and an amorphous portion 804a disposed over a surface of the phosphosilicate portion 802a. In some embodiments, the epitaxial layer 608 formed via the method 700 is deposited at a deposition rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min. In one or more embodiments, epitaxial layer 608 formed via the method 700 exhibits a crystalline growth rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min.

Without being bound by theory, the phosphosilicate portion 802a may be formed via interactions between one or more components within the process gas and the material of the second layer 606. In an exemplary embodiment, the phosphosilicate portion 802a may be composed of SiOP or a derivative thereof.

In some embodiments, the substrate 800a may include a feature 604 on its surface, such as a trench as shown in FIG. 8A. In which case, the deposited epitaxial layer 608 may have a layer thickness 610a at the bottom of the feature, a layer thickness 610b on the sidewall of the feature, and a layer thickness 610c on the top surface of the feature. The layer thickness 610a at the bottom of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The layer thickness 610b on the sidewall of the feature may be from about 5 nm to about 30 nm, such as about 10 nm to about 25 nm, such as about 15 nm to about 20 nm, alternatively about 5 nm to about 10 nm, alternatively about 10 nm to about 15 nm, alternatively about 20 nm to about 25 nm, alternatively about 25 nm to about 30 nm. The layer thickness 610c on the top surface of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

In some embodiments, the layer thickness 610c on the top surface of the feature is the summation of the thickness 802b of the phosphosilicate portion 802a disposed over the surface of the second layer 606 and the thickness 804b of the amorphous portion 804a disposed over the surface of the phosphosilicate portion 802a. The thickness 802b of the phosphosilicate portion 802a disposed over the surface of the second layer 606 may may be about 50 nm or less, such as about 40 nm or less, such as about 30 nm or less, such as about 20 nm or less, such as about 10 nm or less, such as about 5 nm or less, such as about 1 nm to about 3 nm, such as about 1.5 nm to about 2.5 nm, alternatively about 1 nm to about 1.5 nm, alternatively about 1.5 nm to about 2 nm, alternatively about 2 nm to about 2.5 nm, alternatively about 2.5 nm to about 3 nm. The thickness 804b of the amorphous portion 804a disposed over a surface of the phosphosilicate portion 802a may be about 50 nm or less, such as about 40 nm or less, such as about 30 nm or less, such as about 20 nm or less, such as about 10 nm or less, such as about 2 nm to about 10 nm, such as about 4 nm to about 8 nm, such as about 5 nm to about 7 nm, alternatively about 2 nm to about 4 nm, alternatively about 4 nm to about 5 nm, alternatively about 7 nm to about 8 nm, alternatively about 8 nm to about 10 nm.

In some embodiments, the epitaxial layer 608 formed via the method 700 has a dopant concentration of about 1×10²⁰ atom/cm³ to about 5×10²¹ atom/cm³, such as about 5×10²⁰ atom/cm³ to about 1×10²¹ atom/cm³. In at least one embodiment, the crystalline portion 608a of the epitaxial layer 608 formed via the method 700 has a dopant concentration (e.g., phosphorus) of about 1×10²⁰ atom/cm³ to about 5×10²¹ atom/cm³, such as about 5×10²⁰ atom/cm³ to about 1×10²¹ atom/cm³. In one or more embodiments, the crystalline portion 608a of the epitaxial layer 608 formed via the method 700 has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

The method 700 may also include performing an etch operation on the epitaxial layer 608 of the substrate 800a, such as the etch process of operation 512 of the method 500, to produce an etched substrate 800b as shown in FIG. 8B. FIG. 8B shows an etched substrate 800b produced via operation 512 of the method 700, wherein the amorphous portion 804a of the epitaxial layer 608 of substrate 800a is substantially etched from the surface of the phosphosilicate portion 802a. The etched substrate 800b includes the crystalline portion 608a of the epitaxial layer 608 disposed over the surface of the first layer 602 and the phosphosilicate portion 802a disposed over the surface of the second layer 606. In at least one embodiment, the etched substrate 800b includes a feature 604, such as a trench, configured such that the crystalline portion 608a of the epitaxial layer 608 disposed within the feature 604 has a layer thickness 612a of about 5 nm to about 50 nm the bottom of the feature, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The crystalline portion 608a of the epitaxial layer 608 disposed within the feature 604 has layer thickness 612b about 5 nm to about 50 nm on the side wall of the feature, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

The etchant process (e.g., operation 512 of the method 700) may include introducing an etchant to the processing chamber via an etchant gas. The etchant gas may include at least one etchant and a carrier gas. The etchant may be a halogen-containing etchant. Exemplary etchants may include, but are not limited to hydrogen chloride (HCl), germanium hydride (GeH₄), chlorine (Cl₂), boron trichloride (BCl₃), phosphorus trichloride (PCl₃), or any combinations thereof. Higher order germanes such as digermane (Ge₂H₆), or chlorinated germane gas such as germanium tetrachloride (GeCl₄), dichlorogermane (GeH₂Cl₂), or a combination of any two or more thereof, may also be used. In one implementation, the etchant includes HCl and GeH₄. In another implementation, the etchant includes HCl and PCl₃. In yet another implementation, the etchant includes Cl₂ and PCl₃. In yet one another implementation, the etchant includes HCl, GeH₄, and PCl₃. Any suitable halogenated germanium compounds may also be used. In at least one embodiment, the etchant gas includes HCl. In at least one embodiment, the etchant gas includes a carrier gas. The carrier gas may include hydrogen, nitrogen, argon, helium, and any combinations thereof. A carrier gas may be selected based upon specific etchant(s).

In at least one embodiment, the etchant includes HCl and GeH₄. In another embodiment, the etchant includes Cl₂ and GeH₄. In cases where HCl and GeH₄ are used during etching, the flow of HCl and GeH₄ may be introduced into the epitaxy chamber at a GeH₄/HCl ratio of about 1:3 to about 1:7, for example about 1:5. In one exemplary example, GeH₄ is introduced at a flow rate of about 60 sccm and HCl is introduced at 300 sccm, with the carrier gas (N₂) introduced at a flow rate of about 3 SLM.

During operation 512 of the method 700, the etchant gas is introduced to the processing chamber at a rate of about 10 sccm to about 1000 sccm, such as about 50 sccm to about 800 sccm, such as about 100 sccm to about 600 sccm, such as about 200 sccm to about 400 sccm, alternatively about 10 sccm to about 50 sccm, alternatively about 50 sccm to about 100 sccm, alternatively about 100 sccm to about 200 sccm, alternatively about 200 sccm to about 300 sccm, alternatively about 300 sccm to about 400 sccm, alternatively about 400 sccm to about 600 sccm, alternatively about 600 sccm to about 800 sccm, alternatively about 800 sccm to about 1000 sccm. The pressure within the processing chamber is maintained at about 10 Torr to about 600 Torr, such as about 100 Torr to about 500 Torr, such as about 200 Torr to about 400 Torr, alternatively about 10 Torr to about 100 Torr, alternatively about 100 Torr to about 200 Torr, alternatively about 200 Torr to about 300 Torr, alternatively about 300 Torr to about 400 Torr, alternatively about 400 Torr to about 500 Torr, alternatively about 500 Torr to about 600 Torr. The temperature within the processing chamber is maintained at about 300° C. to about 600° C., such as about 350° C. to about 550° C., such as about 400° C. to about 500° C., alternatively about 300° C. to about 350° C., alternatively about 350° C. to about 400° C., alternatively about 400° C. to about 450° C., alternatively about 450° C. to about 500° C., alternatively about 500° C. to about 550° C., alternatively about 550° C. to about 600° C. The etching process is performed for an etch time of about 10 seconds(s) to about 1000 s, such as about 100 s to about 800 s, such as about 400 s to about 600 s, alternatively about 10 s to about 100 s, alternatively about 100 s to about 400 s, alternatively about 400 s to about 500 s, alternatively about 500 s to about 600 s, alternatively about 600 s to about 800 s, alternatively about 800 s to about 1000 s.

In at least one embodiment, the etch process (operation 512) of the method 700 is a selective etch process. The selective etch process selectively removes the amorphous portion (e.g., 804a of FIG. 8A) of the epitaxial layer 608 wherein the amorphous portion 804a of the epitaxial layer 608 of substrate 800a is substantially etched from the surface of the phosphosilicate portion 802a. The etched substrate 800b includes the crystalline portion 608a of the epitaxial layer 608 disposed over the surface of the first layer 602 and the phosphosilicate portion 802a disposed over the surface of the second layer 606. In some embodiments, the etch process removes the amorphous portion 804a of the epitaxial layer 608 at an etch rate of about 0.5 Å/min to about 50 Å/min, such as about 1 Å/min to about 40 Å/min, such as about 10 Å/min to about 30 Å/min, alternatively about 0.5 Å/min to about 1 Å/min, alternatively about 1 Å/min to about 10 Å/min, alternatively about 10 Å/min to about 20 Å/min, alternatively about 20 Å/min to about 30 Å/min, alternatively about 30 Å/min to about 40 Å/min, alternatively about 40 Å/min to about 50 Å/min.

In some embodiments, the method 700 includes performing a plasma etch operation (operation 702) on the epitaxial layer 608 of the substrate (e.g., the etched substrate 800b of FIG. 8B) to form a processed substrate (e.g., the processed substrate 600c of FIG. 6C). In which case, the plasma etch operation (operation 702) of the method 700 substantially removes the phosphosilicate portion 802a from the etched substrate 800b (FIG. 8B) to form the processed substrate 600c (FIG. 6C).

The plasma etch operation (operation 702) of the method 700 may be performed in the epitaxial deposition chamber or a different chamber configured to provide a plasma to the surface of the substrate. In at least one embodiment, the plasma source is a remote plasma source. In some embodiments that implement a remote plasma source, excitation of the gas species allows plasma damage-free substrate processing. The remote plasma etch can be largely conformal and selective towards silicon oxide layers, and thus does not readily etch silicon regardless of whether the silicon is amorphous, crystalline, or polycrystalline.

In some embodiments, the plasma etch operation (operation 702) of the method 700 utilizes a hydrogen plasma. The hydrogen plasma may be formed from a hydrogen process gas (e.g., hydrogen gas (H₂)). The hydrogen process gas may be introduced to the processing volume of the processing chamber at a gas flow rate of about 10 sccm to about 500 sccm, such as about 25 sccm to about 300 sccm, such as about 50 sccm to about 150 sccm, alternatively about 10 sccm to about 25 sccm, alternatively about 25 sccm to about 50 sccm, alternatively about 50 sccm to about 100 sccm, alternatively about 100 sccm to about 150 sccm, alternatively about 150 sccm to about 300 sccm, alternatively about 300 sccm to about 500 sccm.

The plasma may be generated by applying a radio frequency (RF) power to the process gas. In one or more embodiments, the plasma is formed from a remote plasma source to generate the radical species. The RF power may be applied capacitively or inductively. The RF power applied to the process gas may be in the range of about 5 W to about 300 W, such as about 50 W to about 250 W, such as about 100 W to about 200 W, alternatively about 5 W to about 50 W, alternatively about 50 W to about 100 W, alternatively about 100 W to about 150 W, alternatively about 150 W to about 200 W, alternatively about 200 W to about 250 W, alternatively about 250 W to about 300 W. The RF power may be applied to the process gas at a frequency of about 2 MHz to about 30 MHz, such as about 5 MHz to about 25 MHz, such as about 10 MHz to about 20 MHz, alternatively about 2 MHz to about 5 MHz, alternatively about 5 MHz to about 10 MHz, alternatively about 10 MHz to about 15 MHz, alternatively about 15 MHz to about 20 MHz, alternatively about 20 MHz to about 25 MHz, alternatively about 25 MHz to about 30 MHz.

In some embodiments, the plasma etch operation (operation 702) of the method 700 is performed at a pressure of about 1 mTorr to about 500 mTorr, such as about 50 mTorr to about 400 mTorr, such as about 100 mTorr to about 300 mTorr, alternatively about 1 mTorr to about 50 mTorr, alternatively about 50 mTorr to about 100 mTorr, alternatively about 100 mTorr to about 200 mTorr, alternatively about 200 mTorr to about 300 mTorr, alternatively about 300 mTorr to about 400 mTorr, alternatively about 400 mTorr to about 500 mTorr. The plasma etch operation (operation 702) may be performed at a processing temperature of about 50° C. to about 500° C., such as about 100° C. to about 400° C., such as about 200° C. to about 300° C., alternatively about 50° C. to about 100° C., alternatively about 100° C. to about 200° C., alternatively about 300° C. to about 400° C., alternatively about 400° C. to about 500° C.

In some embodiments, the plasma etch operation (operation 702) of the method 700 is performed for a etch time of about 1 s to about 100 s, such as about 10 s to about 75 s, such as about 20 s to about 50 s, alternatively about 1 s to about 10 s, alternatively about 10 s to about 20 s, alternatively about 20 s to about 35 s, alternatively about 35 s to about 50 s, alternatively about 50 s to about 75 s, alternatively about 75 s to about 75 s to about 100 s.

In some embodiments, the plasma etch operation (operation 702) removes the phosphosilicate portion 802a of the epitaxial layer 608 (from the etched substrate 800b of FIG. 8B) at an etch rate of about 0.5 Å/min to about 50 Å/min, such as about 1 Å/min to about 40 Å/min, such as about 10 Å/min to about 30 Å/min, alternatively about 0.5 Å/min to about 1 Å/min, alternatively about 1 Å/min to about 10 Å/min, alternatively about 10 Å/min to about 20 Å/min, alternatively about 20 Å/min to about 30 Å/min, alternatively about 30 Å/min to about 40 Å/min, alternatively about 40 Å/min to about 50 Å/min.

In some embodiments, the epitaxial layer 608 of the processed substrate 600c formed by the method 700 has a dopant concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In at least one embodiment, the epitaxial layer 608 of the processed substrate 600c formed by the method 700 is a crystalline Si:P layer having a phosphorus concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In one or more embodiments, the epitaxial layer 608 of the processed substrate 600c formed by the method 700 has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

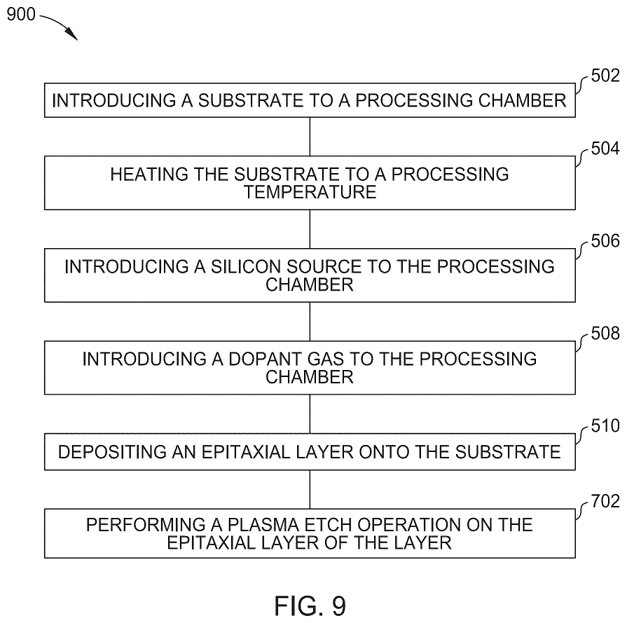

FIG. 9 is a flow chart illustrating a method 900 of forming an epitaxial layer in accordance with one or more aspects of the present disclosure. Similar to the method 500 and/or the method 700, the method 900 includes introducing a substrate (e.g., the substrate 600a of FIG. 6A) to a processing chamber (operation 502). The method 900 may also include heating the substrate and/or the processing volume of the processing chamber to a processing temperature (operation 504). The substrate and/or the processing volume of the processing chamber may be heated to a temperature of 450° C. or less. In at least one aspect, the temperature in the processing chamber may be adjusted so that a reaction region formed at or near an exposed surface of the substrate, or the surface of the substrate itself, is about 450° C. or less. In one example, the substrate is heated to a temperature in a range from about 200° C. to about 450° C., such as about 250° C. to about 400° C., such as about 300° C. to about 350° C., alternatively about 200° C. to about 250° C., alternatively about 250° C. to about 300° C., alternatively about 350° C. to about 400° C., alternatively about 400° C. to about 450° C.

In some embodiments, the method 900 includes introducing a silicon source (operation 506) and/or a dopant gas (operation 508), either sequentially or simultaneously, into the processing volume of the processing chamber. In some embodiments, the silicon source is introduced to the processing chamber via a process gas such that the silicon source is present in the processing volume at a partial pressure of about 10 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

In some embodiments, the process gas includes one or more deposition gases and at least one dopant gas. The deposition gas may include one or more precursor gases selected from Group III precursor gas, Group V precursor gas, Group VI precursor gas, or Group IV precursor gas. In cases where a silicon-containing epitaxial layer is formed, the deposition gas may contain at least a silicon source (e.g., a silicon source gas). Exemplary silicon sources may include, but are not limited to, silanes, halogenated silanes, silicon tetrachloride (SiCl₄), or any combinations thereof. Silanes may include silane (SiH₄) and higher silanes with the empirical formula SiₓH(₂ₓ₊₂), such as disilane (Si₂H₆), trisilane (Si₃H₈), tetrasilane (Si₄H₁₀), pentasilane (Si₅H₁₂), or hexasilane (Si₆H₁₄). Other higher silanes, such as a silicon hydride expressed as SiₙH₂ₙ (n is a natural number equal to or greater than 3), may also be used. For example, cyclotrisilane (Si ₃H₆), cyclotetrasilane (Si₄H₈), cyclopentasilane (Si₆H₁₀), cyclohexasilane (Si₆H₁₂), or cycloheptasilane (Si₇H₁₄). Halogenated silanes may include monochlorosilane (MCS), dichlorosilane (DCS), trichlorosilane (TCS), hexachlorodisilane (HCDS), octachlorotrisilane (OCTS), silicon tetrachloride (STC), or a combination thereof. In some implementations, silanes may include higher order silanes with varying degrees of halogenation in the form of —F, Cl, Br, or I attached to them in order to enable selectivity. For example, Si₂H₄Cl₂ or Si₃H₅Cl₃ etc.

In one exemplary embodiment, the silicon source comprises tetrasilane. In another exemplary embodiment, the silicon source comprises disilane. In yet another exemplary embodiment, the silicon source comprises tetrasilane and disilane.

In some embodiments, the dopant gas is introduced to the processing chamber via a process gas such that the dopant gas is present in the processing volume at a partial pressure of about 5 Torr to about 300 Torr, such as about 50 Torr to about 250 Torr, such as about 100 Torr to about 200 Torr, alternatively about 10 Torr to about 50 Torr, alternatively about 50 Torr to about 100 Torr, alternatively about 100 Torr to about 150 Torr, alternatively about 150 Torr to about 200 Torr, alternatively about 200 Torr to about 250 Torr, alternatively about 250 Torr to about 300 Torr.

The dopant gas may include one or more compounds including phosphorous, boron, arsenic, gallium, or aluminum, depending on the desired conductive characteristic of the deposited epitaxial layer. The deposition gas may optionally contain at least one secondary elemental source, such as a germanium source or a carbon source. Depending on application, other elements, such as metals, halogens or hydrogen may be incorporated within a silicon-containing layer. In one exemplary implementation, the silicon-containing epitaxial layer is phosphorous doped silicon (Si:P), which can be achieved using a dopant such as phosphine (PH₃), phosphorus trichloride (PCl₃), phosphorous tribromide (PBr₃), and phosphates such as tributyl phosphate (TBP).

The silicon source and dopant gas may be introduced to the processing chamber in any suitable order (e.g., silicon source then dopant gas or dopant gas then silicon source). As previously described, the silicon source, the dopant gas, or both being introduced to the processing chamber may, in some embodiments, be referred to as the “process gas”and/or “processing reagents”.

The processing reagents (e.g., the silicon source and the dopant gas) may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. Nitrogen may be utilized as a carrier gas in implementations featuring low temperature (e.g., <600° C.) processes. The carrier gas may have a flow rate from about 1 SLM to about 100 SLM, such as from about 3 SLM to about 30 SLM, such as about 10 SLM to about 20 SLM, alternatively about 1 SLM to about 3 SLM, alternatively about 3 SLM to about 10 SLM, alternatively about 10 SLM to about 15 SLM, alternatively about 15 SLM to about 20 SLM, alternatively about 20 SLM to about 30 SLM, alternatively about 30 SLM to about 35 SLM.

In some embodiments, the silicon source gas may be flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In some embodiments, the dopant gas may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of the silicon source gas relative to the dopant gas is about 1:1 to about 100:1, such as about 1:1 to about 50:1, such as about 1:1 to about 25:1.

In at least one embodiment, the silicon source gas includes disilane and is flowed into the processing chamber at a gas flow rate of about 10 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the dopant gas includes a phosphorus-containing compound (e.g., phosphine). The phosphorus-containing compound may be flowed into the processing chamber at a gas flow rate of about 15 sccm to about 300 sccm, such as about 50 sccm to about 250 sccm, such as about 100 sccm to about 200 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 250 sccm, alternatively about 250 sccm to about 300 sccm. In at least one embodiment, the molar ratio of silicon atoms relative to phosphorus atoms within the process gas is about 1:1 to about 100:1, such as about 1:1 to about 50:1, such as about 1:1 to about 25:1.

The method 900 may also include depositing an epitaxial layer 608 onto the surface of the substrate (operation 510), as illustrated by the substrate 800a shown in FIG. 8A. In some embodiments, the epitaxial layer 608 includes a crystalline portion 608a disposed over a surface of the first layer 602, a phosphosilicate portion 802a disposed over the surface of the second layer 606, and an amorphous portion 804a disposed over a surface of the phosphosilicate portion 802a. In some embodiments, the epitaxial layer 608 formed via the method 900 is deposited at a deposition rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min. In one or more embodiments, epitaxial layer 608 formed via the method 900 exhibits a crystalline growth rate of about 0.5 Å/min to about 150 Å/min, such as about 1 Å/min to about 100 Å/min, such as about 25 Å/min to about 75 Å/min, alternatively about 0.5 Å/min to about 1 Å/min, alternatively about 1 Å/min to about 25 Å/min, alternatively about 25 Å/min to about 50 Å/min, alternatively about 50 Å/min to about 75 Å/min, alternatively about 75 Å/min to about 100 Å/min, alternatively about 100 Å/min to about 150 Å/min.

Without being bound by theory, the phosphosilicate portion 802a may be formed via interactions between one or more components within the process gas and the material of the second layer 606. In an exemplary embodiment, the phosphosilicate portion 802a may be composed of SiOP or a derivative thereof.

In some embodiments, the substrate 800a may include a feature 604 on its surface, such as a trench as shown in FIG. 8A. In which case, the deposited epitaxial layer 608 may have a layer thickness 610a at the bottom of the feature, a layer thickness 610b on the sidewall of the feature, and a layer thickness 610c on the top surface of the feature. The layer thickness 610a at the bottom of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm. The layer thickness 610b on the sidewall of the feature may be from about 5 nm to about 30 nm, such as about 10 nm to about 25 nm, such as about 15 nm to about 20 nm, alternatively about 5 nm to about 10 nm, alternatively about 10 nm to about 15 nm, alternatively about 20 nm to about 25 nm, alternatively about 25 nm to about 30 nm. The layer thickness 610c on the top surface of the feature may be from about 5 nm to about 50 nm, such as about 10 nm to about 40 nm, such as about 20 nm to about 30 nm, alternatively about 5 nm to about 10 nm, alternatively about 10 nm to about 20 nm, alternatively about 30 nm to about 40 nm, alternatively about 40 nm to about 50 nm.

In some embodiments, the layer thickness 610c on the top surface of the feature is the summation of the thickness 802b of the phosphosilicate portion 802a disposed over the surface of the second layer 606 and the thickness 804b of the amorphous portion 804a disposed over the surface of the phosphosilicate portion 802a. The thickness 802b of the phosphosilicate portion 802a disposed over the surface of the second layer 606 may be about 50 nm or less, such as about 40 nm or less, such as about 30 nm or less, such as about 20 nm or less, such as about 10 nm or less, such as about 5 nm or less, such as about 1 nm to about 3 nm, such as about 1.5 nm to about 2.5 nm, alternatively about 1 nm to about 1.5 nm, alternatively about 1.5 nm to about 2 nm, alternatively about 2 nm to about 2.5 nm, alternatively about 2.5 nm to about 3 nm. The thickness 804b of the amorphous portion 804a disposed over a surface of the phosphosilicate portion 802a may be about 50 nm or less, such as about 40 nm or less, such as about 30 nm or less, such as about 20 nm or less, such as about 10 nm or less, such as about 2 nm to about 10 nm, such as about 4 nm to about 8 nm, such as about 5 nm to about 7 nm, alternatively about 2 nm to about 4 nm, alternatively about 4 nm to about 5 nm, alternatively about 7 nm to about 8 nm, alternatively about 8 nm to about 10 nm.

In some embodiments, the epitaxial layer 608 formed via the method 900 has a dopant concentration of about 1×10²⁰ atom/cm³ to about 5×10²¹ atom/cm³, such as about 5×10²⁰ atom/cm³ to about 1×10²¹ atom/cm³. In at least one embodiment, the crystalline portion 608a of the epitaxial layer 608 formed via the method 900 has a dopant concentration (e.g., phosphorus) of about 1×10²⁰ atom/cm³ to about 5×10²¹ atom/cm³, such as about 5×10²⁰ atom/cm³ to about 1×10²¹ atom/cm³. In one or more embodiments, the crystalline portion 608a of the epitaxial layer 608 formed via the method 900 has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

Unlike the method 700, the method 900 does not include the etch process of operation 512. Instead, the method 900 includes performing a plasma etch operation (operation 702) on the epitaxial layer 608 of the substrate (e.g., the substrate 800a of FIG. 8A) to form a processed substrate (e.g., the processed substrate 600c of FIG. 6C). In which case, the plasma etch operation (operation 702) of the method 900 substantially removes both the amorphous portion 804a and the phosphosilicate portion 802a from the substrate 800a (FIG. 8A) to form the processed substrate 600c (FIG. 6C). Without being bound by theory, the etch process of operation 512 of the method 700 can deactivate a portion of the phosphorus content within the epitaxial layer 608, which may cause an increase in resistivity. In some embodiments, utilizing a method that does not include the etch process of operation 512 (e.g., the method 900) can result in the formation of an epitaxial layer 608 with limited phosphorus deactivation, which can enable the formation of an epitaxial layer 608 having a lower resistivity.

The plasma etch operation (operation 702) of the method 900 may be performed in the epitaxial deposition chamber or a different chamber configured to provide a plasma to the surface of the substrate. In at least one embodiment, the plasma source is a remote plasma source. In some embodiments that implement a remote plasma source, excitation of the gas species allows plasma damage-free substrate processing. The remote plasma etch can be largely conformal and selective towards silicon oxide layers, and thus does not readily etch silicon regardless of whether the silicon is amorphous, crystalline, or polycrystalline.

The plasma may be generated by applying a radio frequency (RF) power to the process gas. In one or more embodiments, the plasma is formed from a remote plasma source to generate the radical species. The RF power may be applied capacitively or inductively. The RF power applied to the process gas may be in the range of about 5 W to about 300 W, such as about 50 W to about 250 W, such as about 100 W to about 200 W, alternatively about 5 W to about 50 W, alternatively about 50 W to about 100 W, alternatively about 100 W to about 150 W, alternatively about 150 W to about 200 W, alternatively about 200 W to about 250 W, alternatively about 250 W to about 300 W. The RF power may be applied to the process gas at a frequency of about 2 MHz to about 30 MHz, such as about 5 MHz to about 25 MHz, such as about 10 MHz to about 20 MHz, alternatively about 2 MHz to about 5 MHz, alternatively about 5 MHz to about 10 MHz, alternatively about 10 MHz to about 15 MHz, alternatively about 15 MHz to about 20 MHz, alternatively about 20 MHz to about 25 MHz, alternatively about 25 MHz to about 30 MHz.

In some embodiments, the plasma etch operation (operation 702) of the method 900 is performed for a etch time of about 1 s to about 100 s, such as about 10 s to about 75 s, such as about 20 s to about 50 s, alternatively about 1 s to about 10 s, alternatively about 10 s to about 20 s, alternatively about 20 s to about 35 s, alternatively about 35 s to about 50 s, alternatively about 50 s to about 75 s, alternatively about 75 s to about 75 s to about 100 s.

In some embodiments, the plasma etch operation (operation 702) is performed at a pressure of about 1 mTorr to about 500 mTorr, such as about 50 mTorr to about 400 mTorr, such as about 100 mTorr to about 300 mTorr, alternatively about 1 mTorr to about 50 mTorr, alternatively about 50 mTorr to about 100 mTorr, alternatively about 100 mTorr to about 200 mTorr, alternatively about 200 mTorr to about 300 mTorr, alternatively about 300 mTorr to about 400 mTorr, alternatively about 400 mTorr to about 500 mTorr. The plasma etch operation (operation 702) may be performed at a processing temperature of about 50° C. to about 500° C., such as about 100° C. to about 400° C., such as about 200° C. to about 300° C., alternatively about 50° C. to about 100° C., alternatively about 100° C. to about 200° C., alternatively about 300° C. to about 400° C., alternatively about 400° C. to about 500° C. In some embodiments, the plasma etch operation (operation 702) removes amorphous portion 804a and the phosphosilicate portion 802a from the substrate 800a (FIG. 8A) at an etch rate of about 0.5 Å/min to about 50 Å/min, such as about 1 Å/min to about 40 Å/min, such as about 10 Å/min to about 30 Å/min, alternatively about 0.5 Å/min to about 1 Å/min, alternatively about 1 Å/min to about 10 Å/min, alternatively about 10 Å/min to about 20 Å/min, alternatively about 20 Å/min to about 30 Å/min, alternatively about 30 Å/min to about 40 Å/min, alternatively about 40 Å/min to about 50 Å/min.

In some embodiments, the epitaxial layer 608 of the processed substrate 600c formed by the method 900 has a dopant concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In at least one embodiment, the epitaxial layer 608 of the processed substrate 600c formed by the method 700 is a crystalline Si:P layer having a phosphorus concentration of about 5×10²¹ atoms/cm³ or less, such as about 1×10²⁰ atom/cm³ to about 5×10²¹ atom/cm³, such as about 5×10²⁰ atom/cm³ to about 1×10²¹ atom/cm³. In one or more embodiments, the epitaxial layer 608 of the processed substrate 600c formed by the method 900 has a resistivity of about 0.1 mΩ*cm to about 1 mΩ*cm, such as about 0.2 mΩ*cm to about 0.8 mΩ*cm, such as about 0.4 mΩ*cm to about 0.6 mΩ*cm, alternatively about 0.1 mΩ*cm to about 0.2 mΩ*cm, alternatively about 0.2 mΩ*cm to about 0.4 mΩ*cm, alternatively about 0.4 mΩ*cm to about 0.5 mΩ*cm, alternatively about 0.5 mΩ*cm to about 0.6 mΩ*cm, alternatively about 0.6 mΩ*cm to about 0.8 mΩ*cm, alternatively about 0.8 mΩ*cm to about 1 mΩ*cm.

### EXAMPLES

### Example 1: Determining the Effects of Differing Ratios of Silicon to Dopant

Phosphide doped silicon films (Si:P films) were formed by epitaxially depositing Si:P onto a substrate. Each of the Si:P films were deposited at a deposition temperature of 400° C. and a deposition pressure of about 300 Torr. Disilane and phosphine were flowed into the processing chamber as silicon source and the dopant gas, respectively. The processing reagents (e.g., disilane and phosphine at a ratio of about 50:1 to about 100:1, disilane:phosphine) were introduced to the processing chamber at different feed ratios (based on the partial pressure of each process gas component within the processing chamber), as well as with different amounts of carrier gas (H₂, as measured in standard liters per minute), to determine the effects on the resulting layer thickness, layer growth rate, dopant concentration within the epitaxial layer, and layer resistivity.

It was determined that epitaxial deposition of Si:P films could be achieved using process temperatures previously believed to be incapable of producing such films due to the inactivity of the process gases under such processing conditions. It has been found that low temperature processing regimes (e.g., about 400° C.) may be utilized to form such Si:P films when also implementing high input pressures of the processing reagents (e.g., disiline and phosphine). For instance, it was that increasing the input pressure of the processing reagents results in an increased film growth rate and final film thickness. Furthermore, the ratio of the processing reagents being introduced into the processing chamber affect the overall composition (e.g., phosphorus concentration) and resulting film resistivity. Thus, it was found that there is a balance between the rate of film deposition under such processing conditions and the resulting film properties. Additionally, film deposition rate and film thickness can be greatly increased by reducing the amount of carrier gas utilized in the process gas. Such process conditions utilizing less carrier gas also provide comparable phosphorus concentration and film resistivity.

### Example 2: Post-Deposition Plasma Etching

Phosphide doped silicon films (Si:P films) were formed by epitaxially depositing Si:P onto a substrate. Each of the Si:P films were deposited at a deposition temperature of 400° C. and a deposition pressure of about 450 Torr. Disilane and phosphine were flowed into the processing chamber as silicon source and the dopant gas, respectively. The processing reagents (e.g., disilane and phosphine at a ratio of about 90 sccm:150 sccm, disilane:phosphine) were introduced to the processing chamber to deposit the phosphide doped silicon films. Upon deposition, each of the films were subjected to a plasma etching process to form processed substrates (e.g., method 900). The time in which the films were subjected to the plasma etching process was varied to determine the effect on the resulting resistivity of the films.

It was determined that utilizing a deposition method that doesn't integrate a chemical etch process (e.g., the etch process of operation 512 of the method 700) can provide a processed substrate without significantly increasing the resistivity of the Si:P films. Without being bound by theory, a chemical etch operation can deactivate a portion of the phosphorus content within the epitaxial layer, which may cause an increase in resistivity. In some embodiments, utilizing a method that does not include the chemical etch operation (e.g., the etch process of operation 512 of the method 700) can result in the formation of an epitaxial layer with limited phosphorus deactivation, which can enable the formation of an epitaxial layer having a lower resistivity.

The present disclosure provides methods for selective epitaxial deposition of Si:P layers onto semiconductor substrates at lower than conventional processing temperatures. The epitaxial deposition processes disclosed herein utilize higher than conventional process gas pressures to allow for epitaxial deposition of Si:P layers onto semiconductor substrate at processing temperature lower than about 370° C. A selective etch gas and/or selective etch process may be integrated to effectively remove the amorphous portion of the Si:P epitaxial layer, leaving behind a predominantly crystalline epitaxial layer. The deposition and etch processes of the methods disclosed herein may be cyclically repeated and/or concurrently performed to produce a crystalline Si:P epitaxial layer of suitable thickness onto a semiconductor structure. Additionally, the method by which the etch processes are conducted can dictate the resulting resistivity of the final epitaxial layer. The methods disclosed herein may be integrated into one or more semiconductor fabrication processes, such as deposition of a source/drain module onto a semiconductor substrate and/or deposition of a contact layer subsequent the preparation of a source/drain module.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
positioning a substrate within a processing volume of a processing chamber;
introducing a process gas to the processing chamber, the process gas comprising a silicon source and a dopant gas; and
forming an epitaxial layer on a surface of the substrate at a processing temperature of about 450° C. or less and a partial pressure of the silicon source of about 10 Torr to about 300 Torr.

2. The method of claim 1, wherein the silicon source comprises disilane (Si₂H₆).

3. The method of claim 1, wherein the dopant gas comprises phosphine (PH₃).

4. The method of claim 1, wherein at least one of the silicon source or the dopant gas comprise a carrier gas.

5. The method of claim 1, wherein the dopant gas is introduced to the processing chamber after the silicon source is introduced to the processing chamber.

6. The method of claim 1, wherein the silicon source and the dopant gas are introduced to the processing chamber simultaneously.

7. A method, comprising:
positioning a substrate within a processing volume of a processing chamber;
introducing a process gas to the processing chamber, the process gas comprising a silicon source and a dopant gas;
forming an epitaxial layer on a surface of the substrate, the epitaxial layer comprising an amorphous portion and a crystalline portion, wherein the processing chamber is at a processing temperature of about 450° C. or less during the formation of the epitaxial layer; and
performing an etch operation to remove the amorphous portion from the epitaxial layer.

8. The method of claim 7, wherein the etch operation comprises introducing an etchant to the processing chamber via an etchant gas.

9. The method of claim 8, wherein the etchant is selected from the group consisting of hydrogen chloride (HCl), germanium hydride (GeH₄), chlorine (Cl₂), boron trichloride (BCl₃), phosphorus trichloride (PCl₃), and combinations thereof.

10. The method of claim 7, wherein the silicon source comprises a partial pressure of about 10 Torr to about 300 Torr within the processing chamber during the formation of the epitaxial layer.

11. The method of claim 10, wherein the etch operation removes the amorphous portion of the epitaxial layer at an etch rate of about 0.5 Å/min to about 50 Å/min.

12. The method of claim 7, wherein the etch operation is a plasma etch operation.

13. The method of claim 12, wherein the plasma etch operation utilizes a remote plasma source.

14. The method of claim 7, wherein depositing the epitaxial layer onto the substrate and performing an etch operation on the epitaxial layer are sequential method steps which are cyclically performed.

15. A method, comprising:
positioning a substrate within a processing volume of a processing chamber;
introducing a process gas to the processing chamber, the process gas comprising a silicon source and a dopant gas;
forming an epitaxial layer on a surface of the substrate, the epitaxial layer comprising an amorphous portion, a crystalline portion, and a phosphosilicate portion, wherein the amorphous portion is disposed on a surface of the phosphosilicate portion; and
performing an etch operation on the epitaxial layer to form a processed substrate, the etch operation comprising at least one of a chemical etch operation or a plasma etch operation.

16. The method of claim 15, wherein the etch operation comprises the chemical etch operation, the chemical etch operation comprising introducing an etchant to the processing chamber via an etchant gas to substantially remove the amorphous portion of the epitaxial layer.

17. The method of claim 16, wherein the etch operation further comprises the plasma etch operation, wherein:
the plasma etch operation substantially removes the phosphosilicate portion from the epitaxial layer; and
the plasma etch operation is performed subsequent the chemical etch operation.

18. The method of claim 15, wherein the etch operation comprises the plasma etch operation, the plasma etch operation comprising introducing a plasma to the processing chamber to substantially remove the amorphous portion and the phosphosilicate portion of the epitaxial layer.

19. The method of claim 15, wherein the dopant gas is introduced to the processing chamber after the silicon source is introduced to the processing chamber.

20. The method of claim 15, wherein the silicon source and the dopant gas are introduced to the processing chamber simultaneously.
